(19) United States
(12) Patent Application Publication
(10) Pub. No.: US 2024/0096650 A1
(43) Pub. Date: Mar. 21, 2024

(54) SUBSTRATE PROCESSING APPARATUS AND SUBSTRATE PROCESSING METHOD

(71) Applicant: Tokyo Electron Limited, Tokyo (JP)

(72) Inventors: Shogo FUKUI, Koshi City (JP); Masami YAMASHITA, Koshi City (JP); Tomofumi EMURA, Koshi City (JP)

(21) Appl. No.: 18/367,742

(22) Filed: Sep. 13, 2023

(30) Foreign Application Priority Data
Sep. 20, 2022 (JP) 2022-149428

(51) Int. Cl. H01L 21/67

(52) U.S. Cl. CPC H01L 21/67023; H01L 21/6719; H01L 21/67248; H01L 21/67253

(57) ABSTRACT

A substrate processing apparatus of processing a substrate by using a processing fluid in a supercritical state, the substrate processing apparatus includes: a processing container in which the substrate is accommodated; a supply line connecting the processing container to a fluid source configured to send out the processing fluid in the supercritical state; a discharge line configured to discharge the processing fluid from the processing container; a control valve interposed in the discharge line; and a controller configured to control a pressure in the processing container by adjusting an opening degree of the control valve. In a circulation process in which the processing fluid is supplied to the processing container from the supply line, the controller is configured to adjust the opening degree of the control valve such that each of a pressure-lowering step and a pressure-raising step.

### CROSS-REFERENCE TO RELATED APPLICATION

This application is based upon and claims the benefit of priority from Japanese Patent Application No. 2022-149428, filed on Sep. 20, 2022, the entire contents of which are incorporated herein by reference.

### TECHNICAL FIELD

The present disclosure relates to a substrate processing apparatus and a substrate processing method.

### BACKGROUND

In a semiconductor device manufacturing process in which a laminated structure of an integrated circuit is formed on a front surface of a substrate, such as a semiconductor wafer (hereinafter, referred to as a “wafer”), liquid processing, such as chemical liquid cleaning or wet etching, is performed. In recent years, a drying method using a processing liquid in a supercritical state has been used to remove liquid or the like adhered to a front surface of a wafer in such liquid processing (see, for example, Patent Document 1). Patent Document 1 describes that, in a circulation process of a supercritical drying method, a pressure-lowering step of decreasing an internal pressure of a processing container and a pressure-raising step of raising the internal pressure of the processing container are alternately repeated.

### PRIOR ART DOCUMENTS

### Patent Documents

Patent Document 1: Japanese Patent Laid-Open Publication No. 2018-082099

### SUMMARY

According to one embodiment of the present disclosure, there is provided a substrate processing apparatus of processing a substrate by using a processing fluid in a supercritical state, the substrate processing apparatus includes: a processing container in which the substrate is accommodated; a supply line connecting the processing container to a fluid source configured to send out the processing fluid in the supercritical state; a discharge line configured to discharge the processing fluid from the processing container; a control valve interposed in the discharge line; and a controller configured to control a pressure in the processing container by adjusting an opening degree of the control valve. In a circulation process in which the processing fluid is supplied to the processing container from the supply line while the pressure in the processing container is maintained within a pressure range in which the supercritical state of the processing liquid is maintained, and the processing fluid is discharged from the processing container, the controller is configured to adjust the opening degree of the control valve such that each of a pressure-lowering step of lowering the pressure in the processing container and a pressure-raising step of raising the pressure in the processing container is executed at least once within the pressure range.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a piping system diagram of a supercritical processing apparatus according to an embodiment of a substrate processing apparatus.

FIG. 2 is a schematic cross-sectional view illustrating an example of the configuration of a pressure control valve.

FIG. 3A is a view illustrating fluid flow in a pressure-lowering step and a pressure-raising step of a pressurization process in an embodiment.

FIG. 3B is a view illustrating fluid flow in a normal pressure-raising step of a pressurization process in an embodiment.

FIG. 3C is a view illustrating fluid flow in a circulation process in an embodiment.

FIG. 3D is a diagram illustrating fluid flow in an exhaust process in an embodiment.

FIG. 4 is a graph illustrating changes in pressure in a processing container in an example of a zigzag control performed in the circulation process.

FIG. 5 is a block diagram illustrating an example of feedback control.

FIG. 6 is a graph illustrating changes in pressure in a processing container in another example of the zigzag control performed in the circulation process.

FIG. 7 is a schematic cross-sectional view of a processing container illustrating an example of stay occurring in a processing container.

FIG. 8A is a graph illustrating changes in pressure in a processing container in an example of the zigzag control performed in a normal pressure-raising step of a pressure-raising process.

FIG. 8B is a graph illustrating changes in pressure in a processing container in another example of the zigzag control performed in a normal pressure-raising step of a pressure-raising process.

FIG. 8C is a graph illustrating changes in pressure in a processing container in still another example of the zigzag control performed in a normal pressure-raising step of a pressure-raising process.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A supercritical processing apparatus as an embodiment of the substrate processing apparatus will be described with reference to the accompanying drawings. This supercritical processing apparatus may be used to perform a supercritical drying process in which a substrate W having a liquid (e.g., IPA) adhered to its surface is dried by using a processing fluid in a supercritical state.

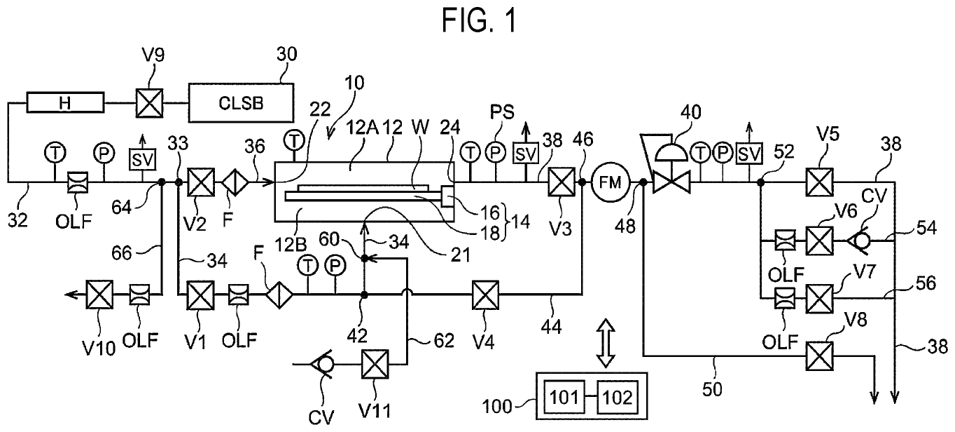

As illustrated in FIG. 1, the supercritical processing apparatus includes a processing unit 10 in which a supercritical drying process is performed. The processing unit 10 includes a processing container 12 and a substrate holding tray 14 (hereinafter, simply referred to as a “tray 14”) that holds a substrate in the processing container 12.

In an embodiment, the tray 14 includes a lid 16 that closes an opening provided in a side wall of the processing container 12 and a substrate support plate (a substrate holder) 18 (hereinafter, simply referred to as a “plate 18”) that is connected to the lid 16 and horizontally extends. A substrate W is placed horizontally on the plate 18 in a state in which the front surface (the device formation surface) thereof faces upward. The plate 18 has, for example, a rectangular or square shape. The area of the plate 18 is larger than that of the substrate W, and when the substrate W is placed at a predetermined position on the plate 18 and viewed from directly below, the substrate W is completely covered with the plate 18.

The tray 14 is horizontally movable between a processing position (closed position) and a substrate delivery position (open position) by a tray moving mechanism (not illustrated). At the processing position, the plate 18 is located in the inner space of the processing container 12 and the lid 16 closes the opening in the side wall of the processing container 12 (the state illustrated in FIG. 1). At the substrate delivery position, the plate 18 is located outside the processing container 12 so that the substrate W can be delivered between the plate 18 and a substrate transfer arm (not illustrated). The moving direction of the tray 14 is, for example, the left-right direction in FIG. 1. The moving direction of the tray 14 may be a direction perpendicular to the paper surface of FIG. 1, in which case the lid 16 may be provided on a front side or a rear side of the plate 18 in the drawing.

When the tray 14 is located at the processing position, the plate 18 divides the inner space of the processing container 12 into an upper space 12A above the plate 18 where the substrate W is present during processing and a lower space 12B below the plate 18. However, the upper space 12A and the lower space 12B are not completely separated. Between the peripheral edge of the tray 14 at the processing position and the inner wall surface of the processing container 12, a gap is formed to serve as a communication path that allows the upper space 12A and the lower space 12B to communicate with each other. In addition, the plate 18 may be provided with a through hole that allows the upper space 12A and the lower space 12B to communicate with each other.

As described above, when the inner space of the processing container 12 is divided into the upper space 12A and the lower space 12B and a communication path is provided to allow the upper space 12A and the lower space 12B to communicate with each other, the tray 14 (the plate 18) may be configured as a substrate stage (substrate holder) that is immovably fixed in the processing container 12. In this case, the substrate transfer arm (not illustrated) enters the processing container in the state in which the lid (not illustrated) provided in the processing container is open, and the substrate is delivered between the substrate stage and the substrate transfer arm.

The processing container 12 includes a first fluid supplier 21 and a second fluid supplier 22 configured to accommodate a pressurized processing fluid (in the present disclosure, supercritical carbon dioxide (hereinafter, also referred to as “CO₂” for convenience)) in the inner space of the processing container 12.

A first fluid supplier 21 is provided below the plate 18 of the tray 14 at the processing position. The first fluid supplier 21 supplies CO₂ into the lower space 12B toward the bottom surface of the plate 18. The first fluid supplier 21 may be configured with a through hole formed in the bottom wall of the processing container 12. The first fluid supplier 21 may be a nozzle body attached to the bottom wall of the processing container 12.

The second fluid supplier 22 is provided to be located on a side of the substrate W placed on the plate 18 of the tray 14 at the processing position. The second fluid supplier 22 may be provided, for example, on one side wall (first side wall) of the processing container 12 or in the vicinity of the side wall. The second fluid supplier 22 supplies CO₂ into the upper space 12A toward an area slightly above the substrate W.

The second fluid supplier 22 may be configured with a plurality of ejection ports arranged in a horizontal direction (e.g., a direction perpendicular to the paper surface of FIG. 1). More specifically, the second fluid supplier 22 may be configured, for example, as a header including a horizontally extending pipe-shaped member pierced with a plurality of holes. It is preferable to configure the second fluid supplier 22 to allow CO₂ to flow along the top surface (front surface) of the substrate W over the entire diameter of the substrate W substantially evenly over the area above the substrate W.

The processing container 12 further includes a fluid discharger 24 configured to discharge the processing fluid from the inner space of the processing container 12. The fluid discharger 24 may be configured as a header including a horizontally extending pipe-shaped member pierced with a plurality of holes in the same manner as the second fluid supplier 22. The fluid discharger 24 may be provided, for example, on the side wall (second side wall) opposite to the first side wall of the processing container 12 where the second fluid supplier 22 is provided, or in the vicinity of the side wall.

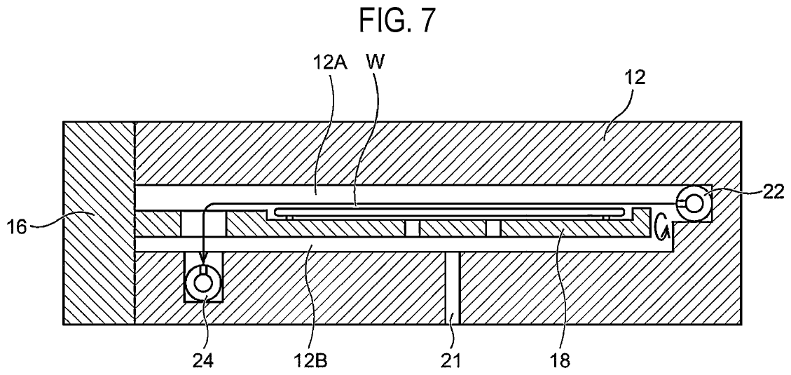

The fluid discharger 24 may be disposed at any position if the CO₂ supplied from the second fluid supplier 22 into the processing container 12 is discharged through the position from the fluid discharger 24 after passing through the area above the substrate W on the plate 18. That is, for example, the fluid discharger 24 may be provided at the bottom of the processing container 12 near the second side wall. In this case, the CO₂ flows through the area above the substrate W in the upper space 12A substantially horizontally, then flows into the lower space 12B through the communication path provided at the peripheral edge of the plate 18 (or the through hole formed in the plate 18), and is then discharged from the fluid discharger 24 (see FIG. 7 to be described later).

Next, a supply/discharge system configured to supply and discharge CO₂ to and from the processing container 12 in the supercritical processing apparatus will be described. In a piping system diagram illustrated in FIG. 1, the members indicated by T surrounded by a circle are temperature sensors, and the members indicated by P surrounded by a circle are pressure sensors. The members labeled OLF are orifices (fixed throttle valves) that reduce the pressure of CO₂ flowing in a downstream pipe of the orifice to a desired value. The members indicated by SV surrounded by a square are safety valves (relief valves), which prevent damage to components of the supercritical processing apparatus, such as pipes or the processing container 12, due to an unexpected excessive pressure. The members labeled F are filters, which remove contaminants, such as particles contained in CO₂. The members labeled CV are check valves (non-return valves). The member indicated by FM surrounded by a circle is a flow meter. The member indicated by H surrounded by a square is a heater that controls the temperature of CO₂. Members denoted by reference numerals VN (N is a natural number) are opening/closing valves, and FIG. 1 illustrates 11 opening/closing valves V1 to V11. The processing container 12 and pipes may be appropriately provided with heat insulating members, heaters, or the like (none of which are illustrated) in order to maintain the state of CO₂ at a desired state.

The supercritical processing apparatus includes a supercritical fluid supply device 30. In the present embodiment, the supercritical fluid is carbon dioxide in a supercritical state (hereinafter, also referred to as “supercritical CO₂”). The supercritical fluid supply device 30 has a well-known configuration including, for example, a carbon dioxide cylinder, a pressurizing pump, a heater, and the like. The supercritical fluid supply device 30 has the ability to send out supercritical CO₂ at a pressure equal to or higher than a supercritical state guarantee pressure (specifically, about 16 MPa), which will be described later.

A main supply line 32 is connected to the supercritical fluid supply device 30. CO₂ flows into the main supply line 32 in a supercritical state from the supercritical fluid supply device 30, but may also be turned into a gaseous state due to subsequent expansion or temperature change. In this specification, the member called “line” may be configured with a pipe (piping member).

The main supply line 32 branches at a branch point 33 into a first supply line 34 and a second supply line 36. The first supply line 34 is connected to the first fluid supplier 21 of the processing container 12. The second supply line 36 is connected to the second fluid supplier 22 of the processing container 12.

A discharge line 38 is connected to the fluid discharger 24 of the processing container 12. A pressure control valve (control valve) 40 is provided in the discharge line 38. By adjusting the opening degree of the pressure control valve 40, the primary side pressure of the pressure control valve 40 can be adjusted, and therefore the pressure in the processing container 12 can be adjusted.

A bypass line 44 branches from the first supply line 34 at a branch point 42 set on the first supply line 34. The bypass line 44 is connected to the discharge line 38 at a connection point 46 set in the discharge line 38. The connection point 46 is located in the upstream of the pressure control valve 40.

A branch discharge line 50 branches off from the discharge line 38 at a branch point 48 set in the discharge line 38 in the upstream of the pressure control valve 40. The downstream end of the branch discharge line 50 is, for example, open to the atmospheric space outside the supercritical processing apparatus or connected to a factory exhaust duct.

Two branch discharge lines 54 and 56 branch off from the discharge line 38 at a branch point 52 set in the discharge line 38. The downstream ends of the branch discharge lines 54 and 56 rejoin the discharge line 38. The downstream end of the discharge line 38 is connected, for example, to a fluid recovery device (not illustrated). A useful component (e.g., IPA (isopropyl alcohol)) contained in the CO₂ recovered by the fluid recovery device is appropriately separated and reused.

A purge gas supply line 62 is connected to a junction 60 set in the first supply line 34 between the branch point 42 and the processing container 12. A purge gas (e.g., nitrogen gas) may be supplied to the processing container 12 via the purge gas supply line 62.

An exhaust line 66 branches off from a branch point 64 set in the main supply line 32 just upstream of the branch point 33.

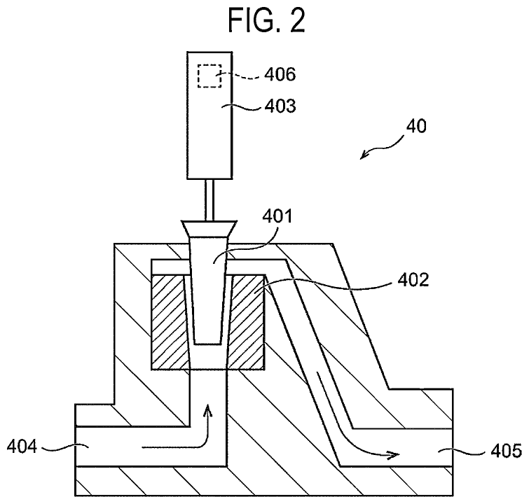

An example of the structure of the pressure control valve 40 is illustrated in FIG. 2. A tapered valve body 401 is inserted into a tapered valve seat 402 which is complementary to valve body 401. A valve actuator 403 moves the valve body 401 up and down to change the opening degree of the pressure control valve 40. When the valve body 401 is displaced upward (downward), a gap between an outer peripheral surface of the valve body 401 and an inner peripheral surface of the valve seat 402 becomes larger (smaller), that is, the opening degree of the valve becomes larger (smaller). When the valve opening degree increases (decreases), the flow of CO₂ from an inlet port 404 to an outlet port 405 increases (decreases), and the pressure in the processing container 12 connected to the inlet port via the discharge line 38 increases (decreases). The actuator 403 incorporates a valve position sensor 406 (not illustrated) configured to detect the position of the valve body 401. The valve position sensor 406 may be an encoder (a linear encoder or rotary encoder) attached to the valve actuator 403. In addition, a pipeline constituting the discharge line 38 on the upstream side (the processing container 12 side) of the pressure control valve 40 is connected to the inlet port 404, and a pipeline constituting the discharge line 38 on the downstream side of the pressure control valve 40 is connected to the outlet port 405.

In the present specification, the terms “position of the valve body 401” and “(valve) opening degree (e.g., a fixed opening degree X or an opening degree offset)” are used, but the former and the latter are parameters that are used interchangeably. In other words, it should be noted that both terms are equivalent to each other and technically mean the same thing even if the terms are interchanged with each other.

As illustrated in FIG. 1, the supercritical processing apparatus includes a controller 100 configured to control the operation of the supercritical processing apparatus. The controller 100 is, for example, a computer and includes a calculator 101 and a storage 102. The storage 102 stores programs for controlling various processes executed in the supercritical processing apparatus (or a substrate processing system including the supercritical processing apparatus). The calculator 101 controls the operation of the supercritical processing apparatus by reading and executing a program stored in the storage 102. The program may be recorded in a non-transient computer-readable storage medium and installed in the storage 102 of controller 100 from the storage medium. The non-transient computer-readable storage medium is, for example, a hard disk (HD), a flexible disk (FD), a compact disk (CD), a magneto-optical disk (MO), a memory card, or the like.

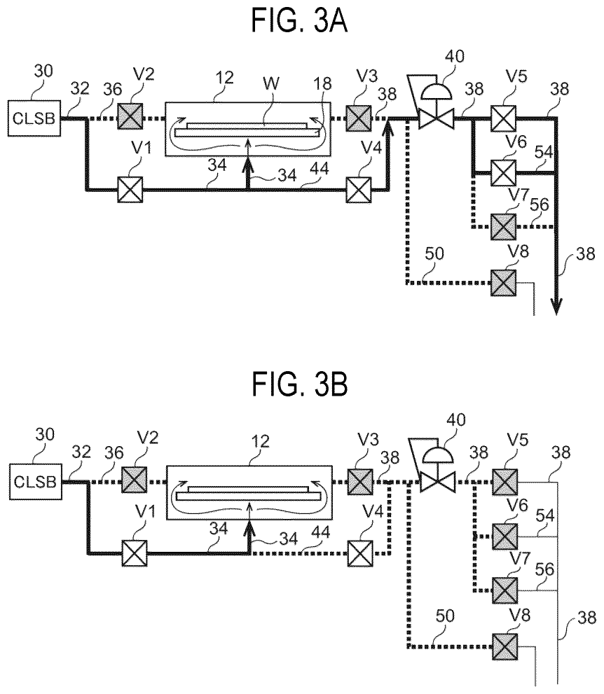

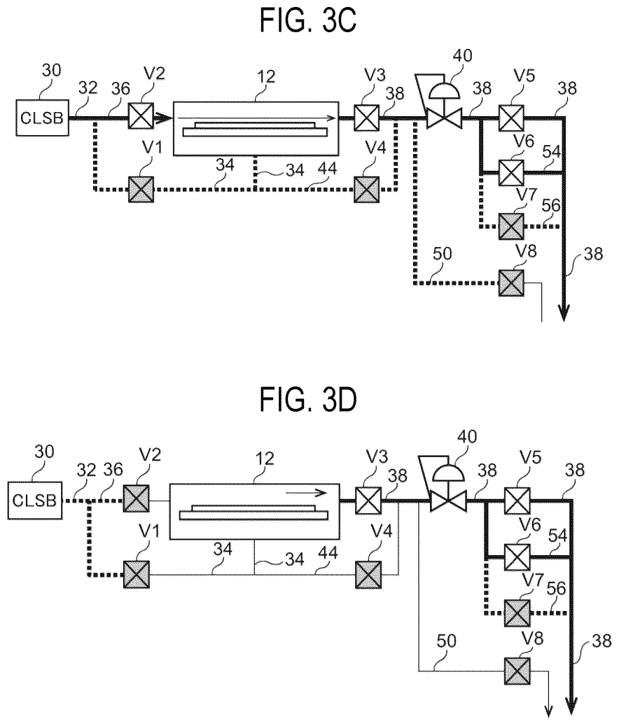

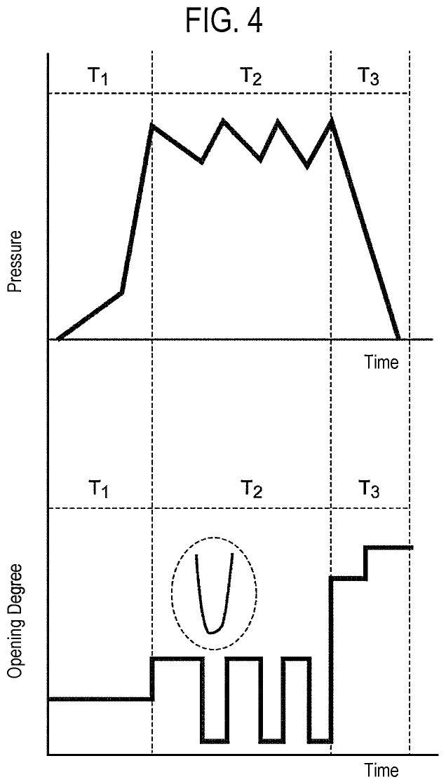

Next, an exemplary embodiment of a drying method (substrate processing method) performed by using the above-described supercritical processing apparatus will be described with reference to FIGS. 3A to 3D and FIG. 4 as well. The drying method to be described below is automatically executed under the control of the controller 100 based on a processing recipe and a control program stored in the storage 102.

In the following series of processes, the pressure in the processing container 12 is detected by a pressure sensor provided in a pipe immediately adjacent to the fluid discharger 24 and connected to the fluid discharger 24 of the processing container 12. In FIG. 1, this pressure sensor is denoted by reference symbol PS and hereinafter also referred to as a “pressure sensor PS” for convenience. A value detected by this pressure sensor PS may be considered to be approximately equal to the pressure in the processing container 12. In addition, the pressure in the processing container 12 may be measured by a pressure sensor (not illustrate) provided inside the processing container 12.

In FIGS. 3A to 3D, the opening/closing valves that are shaded in black are in the closed state, and the opening/closing valves that are not shaded are in the open state. In FIGS. 3A to 3D, the lines in which CO₂ is flowing are indicated by thick solid lines, and the lines in which CO₂ stays under a certain pressure are indicated by thick broken lines.

The horizontal axis of the graph in FIG. 4 represents time, the upper vertical axis of the graph represents the pressure in the processing container 12, and the lower vertical axis of the graph represents the opening degree of the pressure control valve 40. In the graph of FIG. 4, “T1” is a period during which a pressure-raising process is performed, “T2” is a period during which a circulation process is performed, and “T3” is a period during which an exhaust process is performed. In the graph of FIG. 4, a change in the opening degree of the pressure control valve 40 is illustrated as a rectangular wave. However, especially in the period T2, as is apparent from a control mode to be described later, in reality, there are slopes between the peaks and the bottoms and the vicinities of the peaks and the bottoms are rounded (see the curve surrounded by the broken line in FIG. 4).

### [Carry-In Process]

A substrate W, such as a semiconductor wafer, is placed on the plate 18 of the tray 14, which is on standby at a substrate transfer position, by a substrate transfer arm (not illustrated) in a state in which recesses of a pattern on the front surface thereof are filled with IPA and puddles (liquid films) of IPA are formed on the front surface thereof. In addition, for example, in a single-wafer cleaning apparatus, the substrate W has sequentially subjected to (1) chemical liquid processing, such as wet etching and chemical liquid cleaning, (2) rinsing processing in which the chemical liquid is washed away with a rinsing liquid, and (3) IPA replacement processing in which the rinsing liquid is replaced with IPA to form the puddles of IPA. When the tray 14 on which the substrate W are placed moves to the processing position, a closed processing space is formed in the processing container 12, and the substrate W is located in the processing space.

### [Pressure-Raising Process]

Next, a pressure-raising process is executed. The pressure-raising process includes an initial decelerated pressure-raising step and a normal pressure-raising step followed by a decelerated pressure-raising step.

The opening/closing valve V9 is normally open and the opening/closing valve V11 is normally closed from a point of time of starting the pressure-raising process to a point of time of terminating the discharge process, and these opening/closing valves will not be mentioned in the following description. The opening/closing valve V8 may be open during an exhaust process, which makes it possible to shorten an exhaust time. In the following description, it is assumed that the opening/closing valve V8 is normally closed.

### <Decelerated Pressure-Raising Step>

First, as illustrated in FIG. 3A, the opening/closing valves V2, V3, V7, and V8 are closed, and the opening/closing valves V1, V4, V5, and V6 are opened. The pressure control valve 40 is kept open at an appropriate opening degree (e.g., about 20%). CO₂ sent in a supercritical state from the supercritical fluid supply device 30 to the main supply line 32 flows into the first supply line 34, and some (e.g., about 30 to 60%) of the CO₂ flows into the processing container 12 through the first fluid supplier 21. In addition, the rest of the CO₂ that has flowed through the first supply line 34 flows through the bypass line 44 into the discharge line 38 rather than into the processing container 12, and is dumped into a factory exhaust duct or recovered for reuse after flowing through the discharge line 38. By adjusting the opening degree of the pressure control valve 40, the ratio of the flow rate of CO₂ flowing into the processing container 12 and the flow rate of CO₂ flowing through the bypass line 44 can be adjusted, and accordingly, the inflow speed of the CO₂ into the processing container 12 and the pressure-raising speed of the processing container 12 can be adjusted.

Immediately after the start of the pressure-raising step, the pressure of CO₂ sent out in the supercritical state from the supercritical fluid supply device 30 drops significantly when the CO₂ flows into the processing container 12 which has a relatively large volume and is in a normal pressure state. That is, at the initial stage of introduction of CO₂ into the processing container 12, the pressure of CO₂ in the processing container 12 is lower than a critical pressure (e.g., about 8 MPa), so the CO₂ is in a gaseous state. Since the difference between the pressure in the first supply line 34 and the pressure in the processing container 12 which is in the normal pressure state is very large, the CO₂ flows into the processing container 12 at a high flowing speed immediately after the start of the decelerated pressure-raising step. When CO₂ (particularly high-speed gaseous CO₂) collides with the substrate W or flows in the vicinity of the substrate W, breaking (local evaporation or fluctuation) of puddles of IPA existing at the peripheral edge of the substrate W occurs, resulting in pattern collapse may occur.

However, by setting a decelerated pressure-raising step at the beginning of the pressure-raising process to suppress the inflow rate of CO₂ in the processing container 12, pattern collapse due to the above-described mechanism can be suppressed. The opening/closing valve V10 may open only at the beginning of the decelerated pressure-raising step or throughout the decelerated pressure-raising step to allow some of the CO₂ flowing through the main supply line 32 to escape to the exhaust line 66. By doing so, the flow speed of the CO₂ flowing into the processing container 12 from the first fluid supplier 21 can be further lowered, and pattern collapse due to the above-described mechanism can be more reliably suppressed.

In the pressure-raising process (especially the decelerated pressure-raising step thereof), by causing CO₂ to flow into the processing container 12 via the first fluid supplier 21, the inflowing CO₂ collides with the plate 18 of the tray 14, then bypasses the plate 18 and enters the upper space 12A where the substrate W is present (see arrows in FIG. 3A). Therefore, when gaseous CO₂ reaches the vicinity of the substrate W, the flowing speed of CO₂ is relatively low. Therefore, pattern collapse due to the above-described mechanism can be suppressed.

The pattern collapse due to the above mechanism can occur only at the beginning of introduction of CO₂ into the processing container 12. This is because as the pressure in the processing container 12 increases, the flowing speed of CO₂ flowing into the processing container 12 via the first fluid supplier 21 decreases. Therefore, it suffices to execute the decelerated pressure-raising step for a relatively short period of time, for example, about 10 to 20 seconds.

### <Normal Pressure-Raising Step>

Next, as illustrated in FIG. 3B, the opening/closing valves V5 and V6 are closed. This switching may be performed, for example, when the pressure in the processing container 12 (a value detected by the pressure sensor PS) exceeds a predetermined threshold value. Alternatively, switching may be performed when a predetermined time (e.g., about 10 seconds as described above) has elapsed from the start of the decelerated pressure-raising step.

With the switching of the opening/closing valves, the CO₂ flowing from the bypass line 44 to the discharge line 38 and flowing through the discharge line 38 and the branch discharge line 54 is blocked by the opening/closing valves V5 and V6. Accordingly, the lines 44, 38, 50, 54, and 56 are filled with CO₂ and the pressure in the lines increases. Then, the flow rate of CO₂ flowing from the first supply line 34 to the bypass line 44 also decreases, and the pressure in the processing container 12 increases at a higher speed than that in the decelerated pressure-raising step.

When the pressure in the processing container 12 exceeds the critical pressure of CO₂ (about 8 MPa), the CO₂ present in the processing container 12 (CO₂ not mixed with IPA) is turned into a supercritical state. When the CO₂ in the processing container 12 is turned into the supercritical state, the IPA on the substrate W begins to dissolve into the supercritical CO₂.

After the pressure in the processing container 12 exceeds the critical pressure of CO₂, regardless of the concentration and temperature of the IPA in the mixed fluid (CO₂+IPA) on the substrate W, the above-described normal pressure-raising step continues until a pressure that guarantees that the CO₂ maintained in the processing container 12 (hereinafter, referred to as a “supercritical state guarantee pressure”) is obtained (preferably until a pressure slightly higher than the supercritical state guarantee pressure is obtained). Although the supercritical state guarantee pressure depends on the temperature in the processing container 12, the supercritical state guarantee pressure is approximately 16 MPa in the present embodiment. When the pressure in the processing container 12 reaches the above-mentioned supercritical state guarantee pressure, pattern collapse due to a local phase change (e.g., vaporization) of the mixed fluid in the plane of the substrate W no longer occurs. In addition, this local phase change occurs due to non-uniformity of the concentration of IPA in the mixed fluid within the surface of the substrate W, and may occur especially in an area exhibiting the concentration of IPA that makes the critical temperature high.

### [Circulation Process]

When it is identified by a pressure sensor that the pressure in the processing container 12 has reached the supercritical state guarantee pressure, as illustrated in FIG. 3C, the opening/closing valves V2, V3, V5, and V6 are opened, the opening/closing valves V1 and V4 are closed, and transition to a circulation process is performed.

Since the opening/closing valves V5 to V8 were closed until immediately before switching between the opening and closing of the opening/closing valves, the pressures in the lines 44, 38, 50, 54, and 56 are generally at the supercritical state guarantee pressure. Of course, the pressure in the first supply line 34 is also at approximately the above-described supercritical state guarantee pressure. Therefore, it is possible to prevent the pressure in the processing container 12 from temporarily decreasing immediately after the opening of the opening/closing valve V3, and it is possible to prevent or greatly suppress a sudden change in the pressure in the processing container 12 before and after switching the opening/closing valve.

In the circulation process, the supercritical CO₂ supplied from the second fluid supplier 22 into the processing container 12 flows through the area above the substrate and is then discharged from the fluid discharger 24. In this case, a laminar flow of supercritical CO₂ flowing substantially parallel to the front surface of the substrate W is formed in the processing container 12. The IPA in the mixed fluid (IPA+CO₂) on the front surface of the substrate W exposed to the laminar flow of supercritical CO₂ is replaced with the supercritical CO₂. Ultimately, almost all of the IPA on the surface of the substrate W is replaced with the supercritical CO₂.

The mixed fluid consisting of the IPA and supercritical CO₂ discharged from the fluid discharger 24 is recovered after flowing through the discharge line 38 (and the branch discharge lines 54 and 56). The IPA included in the mixed fluid may be separated and reused.

In the present embodiment, during the circulation process, a zigzag control is performed to repeat the pressure decrease (the pressure-lowering step) and the pressure increase (the pressure-raising step) in the processing container 12. This zigzag control is performed to prevent the fluid from staying in the same place continuously by changing the flow of the fluid in the processing container 12 (see also FIG. 7 to be described later). Several pressure change patterns are conceivable in this zigzag control (modifications will be described later), but here, as illustrated in FIG. 4, it is assumed that the zigzag control is performed immediately after the completion of the pressure-raising process, and transition to an exhaust process is performed immediately after the completion of the zigzag control.

That is, here, when the pressure-raising process (normal pressure-raising step) is completed (for example, when the pressure sensor PS detects that the pressure in the processing container 12 has reached 17 MPa), the initial (first) pressure-lowering step in the circulation process is started as follows by using the detection as a trigger.

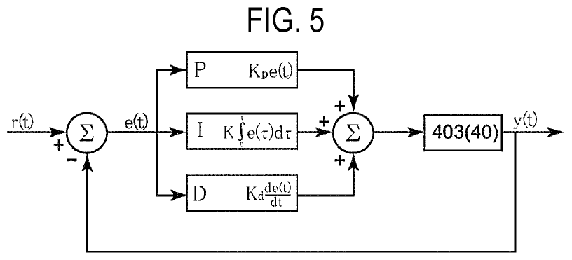

Here, the pressure-lowering step is executed by feedback-controlling the opening degree of the pressure control valve 40 by using a feedback control system as illustrated in FIG. 5. Here, the feedback control is described as being performed by PI control that does not use a differential term, but PID control may be performed.

### <First Pressure-Lowering Step>

A target opening degree of the pressure control valve 40 (for example, the opening degree that can be expected to be achieved when the target value of the pressure in the processing container 12 is 16 MPa) is given as a target value r given to the feedback control system. The target opening degree is given by “fixed opening degree X+opening degree offset ΔX”. The fixed opening degree X and the opening degree offset ΔX will be described later. The target value r is constant during one step of the zigzag control (that is, one pressure-lowering step or one pressure-raising step) and is not a value that changes over time.
Feedback gains (here, a P-gain for pressure-lowering (Kp) and an I-gain for pressure-lowering (Ki)) are given to the feedback control system. When performing the PI control as described above, no D gain (Kd) is provided. Setting of the P-gain and I-gain will also be described later.
An output value y is the position of the valve body 401 of the pressure control valve 40 detected by the valve position sensor 406 of the pressure control valve 40 (or the valve opening degree calculated based on the position of the valve body 401).
A manipulated amount u is the amount of movement of the valve body 401 moved by the valve actuator 403 of the pressure control valve 40, and can also be detected by the valve position sensor 406.

In this feedback control, the manipulated amount u(t) corresponding to the P-gain and the I-gain is determined based on “deviation e(t)=target value r−output value y(t)”, and the actual opening degree approaches the target value r (the target opening degree of the pressure control valve 40). The change speed of the actual opening degree of the pressure control valve 40 is determined depending on the P-gain and the I-gain. For simplification of description, such feedback control is also called “opening degree FB control”.

At least while the circulation process is being executed, changes in the pressure in the processing container 12 are monitored by the pressure sensor PS and stored in the storage 102 (which may be another suitable memory) of the controller 100. In other words, the output log of the pressure sensor PS is stored in the storage 102 at least while the circulation process is being performed. The stored data is used to modify an opening degree offset ΔX and a feedback gain, which will be detailed later. The detected pressure data in the processing container 12 is not directly involved to the feedback control of the opening degree of the pressure control valve 40.

### <First Pressure-Raising Step>

When the pressure sensor PS detects that the pressure in the processing container 12 has reached the target pressure (e.g., 16 MPa), by switching the target value r and the feedback gain by using the detection as a trigger, a first transition from the first pressure-lowering step to the first pressure-raising step is performed.

The target value r given to the feedback control system in the first pressure-raising step is, for example, the target opening degree of the pressure control valve 40 that can be expected to achieve when the target value of the pressure in the processing container 12 is 17 MPa. This target opening degree is given by “fixed opening degree X+opening degree offset ΔX”, as in the pressure-lowering step. The feedback gains (the P-gain and the I-gain) provided to the feedback control system for the first pressure-raising step may be the same as the feedback gains used in the first pressure-lowering step. In this case, only the target value r is switched. The feedback gains (the P-gain and the I-gain) used in the first pressure-raising step may be different from the feedback gains used in the first pressure-lowering step. The definitions of the output value y and the manipulated amount u are the same as those in the first pressure-lowering step.

### <Second Pressure-Lowering Step>

When the pressure sensor PS detects that the pressure in the processing container 12 has reached the target pressure (e.g., 17 MPa), by performing the switching of the target value r and the switching of the feedback gains (which may not be performed) by using the detection as a trigger, a transition from the first pressure-raising step to the second pressure-lowering step is performed.

### <Second Pressure-Raising Step>

When the pressure sensor PS detects that the pressure in the processing container 12 has reached the target pressure (e.g., 16 MPa), by performing the switching of the target value r and the switching of the feedback gains (which may not be performed) by using the detection as a trigger, a transition from the second pressure-lowering step to the second pressure-raising step is performed.

As described above, the pressure-lowering step and the pressure-raising step are alternately repeated a predetermined number of times. When the final pressure-raising step is completed, the circulation process is terminated and transition to an exhaust process is performed. In switching between the pressure-lowering step and the pressure-raising step, a trigger for the switching is detection of a predetermined pressure by the pressure sensor PS, and what is always changed at the time of switching is the target value r (the target opening degree of the pressure control valve 40). The target value r may be the same for all the pressure-lowering steps (or pressure-raising steps), or the target value r for one pressure-lowering step may be different from the target value r for another pressure-lowering step. Feedback gains may be maintained at the same value during the zigzag control, or feedback gains in one or more steps (pressure-lowering steps or pressure-raising steps) may differ from feedback gains in other steps.

By executing the circulation process for a predetermined time, the replacement of IPA on the substrate W with supercritical CO₂ is completed. Next, transition to the discharge process is performed.

### [Discharge Process]

In the discharge process, as illustrated in FIG. 3D, the opening/closing valve V2 is closed to stop the supply of supercritical CO₂ to the processing container 12, and the opening degree of the pressure control valve 40 is set to a predetermined value (e.g., 70% to 90%). As a result, the pressure in the processing container 12 decreases to normal pressure. As a result, the supercritical CO₂ which has been present in a pattern of the substrate W is turned into a gas and leaves the pattern, and the gaseous CO₂ is discharged from the processing container 12. Drying of the substrate W is thus completed.

### [Carry-Out Process]

The plate 18 of the tray 14 on which the dried substrate W is placed moves out of the processing container 12 and into the substrate delivery position. The substrate W is taken out from the plate 18 by a substrate transfer arm (not illustrated) and accommodated in, for example, a substrate processing container (not illustrated).

### [Correction of Control Parameters]

Next, correction of control parameters used in the zigzag control using an output log of the pressure sensor PS stored in the storage 102 will be described. Correction of control parameters may be performed by executing a control parameter correction program stored in the storage 102 by the calculator 101 of the controller 100 and executing the following procedure. Parameters to be corrected include an opening degree offset ΔX and feedback gains (a P-gain and an I-gain in the present embodiment). These parameters may be set to values determined by experiments, for example, when starting up this supercritical processing apparatus or when developing a supercritical processing apparatus having the same specifications.

The main reason for having to correct these parameters is a change over time in the condition of the pressure control valve 40. Specifically, for example, the surfaces of the valve body 401 and the valve seat 402 facing each other in the pressure control valve 40 wear out over time of use. With the wear, the actual valve opening degree (the gap between the valve body and the valve seat) for the same valve body position (vertical position in the drawing) gradually increases. This affects not only the peak (maximum) and bottom (minimum) pressures in the processing container 12 actually obtained in the zigzag control, but also the pressure change behavior.

In the feedback control used in the above-described the zigzag control, the pressure in the processing container 12 (a value detected by the pressure sensor PS) is not included in any of the target value r, the output value y, and the manipulated amount u. Therefore, it is impossible to compensate for the deviation of the actual pressure in the processing container 12 from the target pressure by the feedback control itself. In order to solve this problem, the opening degree offset ΔX and the feedback gains are corrected.

The feedback gains affect not only the overall pressure gradient (time differential of pressure) during the zigzag control, but also the pressure change behavior near the peak pressure and near the bottom pressure. The feedback gains are determined not only by considering the overall pressure gradient, but also by reducing hunting or overshoot that may occur near the peak pressure and near the bottom pressure.

In principle, the fixed opening degree X may not be changed unless the pressure control valve 40 is replaced. The opening degree offset ΔX is a compensation value added to the fixed opening degree X in order to compensate for deterioration over time of the pressure control valve 40, and the initial value thereof is, for example, zero. Unless the opening degree offset ΔX is properly set, damage to components due to excessive pressure or release of the supercritical state due to pressure drop may occur depending on the setting of feedback gains.

As an example, the correction of the opening degree offset ΔX and the feedback gains based on the output log of the pressure sensor PS in the first pressure-lowering step will be described. The storage 102 stores a pressure change model that defines desired changes in pressure (changes over time in pressure value and pressure gradient) in the processing container 12 at each pressure-lowering step and each pressure-raising step. The output log of the pressure sensor PS for the first pressure-lowering step is compared with the pressure change model for the first pressure-lowering step. In order to make the former approach the latter, the opening degree offset ΔX and the feedback gains are corrected based on the comparison results.

Correction of the opening degree offset ΔX is performed as follows. That is, the actual opening degree of the pressure control valve 40 (which is recorded as a log of the output of the valve position sensor 406) at the time when the pressure sensor PS detects that the pressure in the processing container 12 has reached the target pressure (e.g., 16 MPa) is compared with the target opening degree of the pressure control valve 40, and the opening degree offset ΔX is changed depending on the difference. The amount of change in the opening degree offset ΔX may, for example, completely match the difference between the actual opening and the target opening, but is not limited thereto.

The value (X+ΔX) obtained by adding the changed opening degree offset ΔX to the fixed opening degree X may be used as the target value r (the target opening degree of the pressure control valve 40) in the “later pressure-lowering step”. As above, the “later pressure-lowering step” may be, for example, the second pressure-lowering step of the circulation process for the same substrate W, or the first pressure-lowering step of the processing process for the substrate W to be processed next.

In addition, the concept of the opening degree offset ΔX may not be used. That is, the fixed opening degree X may be changed, for example, each time a processing step (a pressure-lowering step or a pressure-raising step) is terminated. In other words, for example, a value corresponding to the opening degree offset ΔX may be added to the fixed opening degree X each time one processing step is terminated, and the result may be set as a new fixed opening degree X (update of fixed opening degree).

Correction of the feedback gains may be performed by a mathematical operation or simulation. Since feedback control in the zigzag control is performed by a very simple system in which the valve actuator is operated based on the deviation of the actual opening degree of the pressure control valve 40 from the target opening degree to bring the actual opening degree closer to the target opening degree, the correction operation is easy. In addition, when the opening degree offset ΔX is changed, the deviation also changes, so a change in the opening degree offset ΔX is also considered in the correction operation.

The corrected P-gain for pressure-lowering and I-gain for pressure-lowering may be used in a “later pressure-lowering step”. The “later pressure-lowering step” may be, for example, the second pressure-lowering step of the circulation process for the same substrate W, or the first pressure-lowering step of the processing process for the substrate W to be processed next.

Correction of the opening degree offset ΔX and the feedback gains for pressure-raising may also be performed in the same manner.

The opening degree offset ΔX and the feedback gains may be corrected, for example, at the following times.

(A1) Each time the processing of one substrate is completed

(A2) Each time the processing of a predetermined number of substrates is completed

(B) Each time one pressure-lowering step (or one pressure-raising step) is completed

For example, in the case of (A1), when the processing conditions are the same for all pressure-lowering steps (or all pressure-raising steps) included in one circulation process, a correction may be made based on the amount of correction obtained from the log of the last pressure-lowering step (or the last pressure-raising step). Alternatively, the correction may be made based on the average value of the amount of correction obtained from the log of each pressure-lowering step (or each pressure-raising step).

Correction of the opening degree offset ΔX and the feedback gains may not be performed unless necessary (when it can be determined that there is no problem even the previous values are maintained).

By correcting the opening degree offset ΔX and the feedback gains at an appropriate timing, undesirable pressure build-up in the processing container 12 or in the lines connected thereto, which may lead to processing failure, damage to apparatus components, can be prevented.

### [Modification of Pressure-Raising Process]

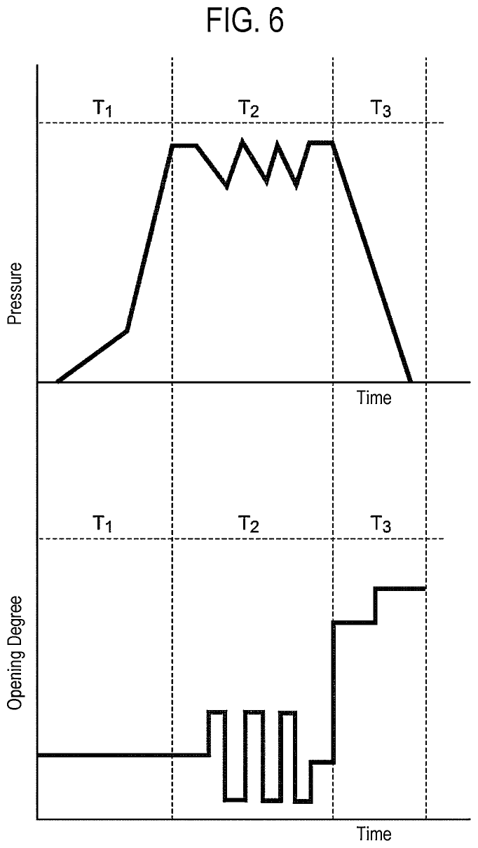

As illustrated in FIG. 6, the pressure in the processing container 12 may be kept constant during at least one time interval of the circulation process. In other words, a constant-pressure step may be added to the circulation process in addition to the pressure-lowering step and the pressure-raising step. In FIG. 6, constant-pressure steps are provided in the first and last time intervals of the circulation process, but a constant-pressure step may be provided only in the first or last time interval, or only in a time interval in the middle of the circulation process.

When the constant-pressure step is executed at the beginning of the circulation process, for example, the following procedure may be executed. At least at the end of the pressure-raising step (which may be the entire period of the pressure-raising step), the controller 100 controls the pressure control valve 40 to fix the opening degree of the pressure control valve 40 to a predetermined fixed opening degree.

This fixed opening degree is used as the initial opening degree command value in the constant-pressure step. This fixed opening degree (the initial opening degree) may be defined as a valve position (or an opening degree corresponding thereto) detected by the valve position sensor 406 of the pressure control valve 40 when the pressure in the processing container 12 converges to 17 MPa, in the case where the feedback control (hereinafter, referred to as “pressure FB control” for simplicity) is performed assuming that the target value r given to the feedback control system is the pressure in the processing container 12 (here, 17 MPa), the output value y is the pressure in the processing container 12 detected by the pressure sensor PS, and the manipulated amount u is the moving amount of the valve body 401 moved by the valve actuator 403 of the pressure control valve 40. The fixed opening degree may be determined by experiments using an actual supercritical processing apparatus.

In this modification, the pressure-raising of the interior of the processing container 12 is performed while fixing the pressure control valve 40 to a fixed opening degree at least at the end of the pressure-raising step, and when the pressure sensor PS detects that the pressure in the processing container 12 has reached 17 MPa, the above-described pressure PB control is started. As a result, in the constant-pressure step, the pressure in the processing container 12 can be stably maintained at a constant pressure. When the length of time for the constant-pressure step is short, the pressure in the processing container 12 may be maintained at a constant pressure by fixing the pressure control valve 40 to a fixed opening degree. However, in order to maintain the pressure in the processing container 12 at a desired pressure, it is preferable to perform the above-described pressure FB control.

When performing the above-described zigzag control after the constant-pressure step, the pressure-lowering step may be started as previously described after the constant-pressure step is performed for a predetermined length of time (i.e., by using the end of the countdown by the timer of the controller 100 as a trigger). With the transition from the constant-pressure step to the pressure-lowering step, the mode of feedback control transits from the pressure FB control to opening degree FB control.

When the constant-pressure step is executed after the zigzag control, transition to the constant-pressure step may be performed, for example, after the pressure-raising step is completed. In this case, the target opening degree (fixed opening degree X+opening degree offset ΔX) in the pressure-raising step immediately before the constant-pressure step is used as it is as the initial opening command value (fixed opening degree) in the constant-pressure step, and with the transition from the pressure-raising step to the constant-pressure step, the opening degree FB control transits to the pressure FB control.

When the circulation process includes the constant-pressure step, the correction of the above-described opening degree offset ΔX may be performed based on the deviation between the actual opening degree of the pressure control valve 40 when the pressure is stabilized in the constant-pressure step and the above-described fixed opening degree. By doing so, it is possible to correct the opening degree offset ΔX with higher accuracy.

### [Modification of Zigzag Control]

The pressure gradients (pressure change rates per unit time) in pressure-lowering steps or pressure-raisings in zigzag control, or the bottom (minimum) pressures (pressure target values for the pressure-lowering steps) or the peak (maximum) pressures (pressure target values for the pressure-raising steps) may be equal to each other in respective pressure-lowering steps and respective pressure-raising steps. Alternatively, among a plurality of pressure-lowering steps (or pressure-raising steps), at least one pressure-lowering step (or pressure-raising step) may have a different pressure gradient or bottom pressure (or peak pressure) relative to the other pressure-lowering steps (or pressure-raising steps).

As the circulation process progresses, IPA is replaced with CO₂, so the mixing ratio (molar ratio) between IPA and CO₂ changes, and as the mixing ratio changes, the pressure at which the mixed fluid is guaranteed to be maintained in the supercritical state (supercritical state guarantee pressure) changes. In the zigzag control, pattern collapse may occur when the bottom pressure in the pressure-lowering step (pressure target value in the pressure-lowering step) is lowered below the supercritical state guarantee pressure. Therefore, when changing the bottom pressure in the pressure-lowering step, it is desirable to determine the bottom pressure in the pressure-lowering step (target pressure value in the pressure-lowering step) depending on the progress of the circulation process.

According to the various embodiments described above, since the flow mode of the fluid (CO₂ or mixed fluid of CO₂ and IPA) in the processing container 12 changes by performing the zigzag control in the circulation process, it is possible to prevent the fluid from staying at a specific area in the processing container 12. Therefore, it is possible to prevent contaminants derived from IPA, contaminants detached from substrates W, and contaminants detached from components exposed to the atmosphere in the processing container 12 from staying in the processing container 12 and contaminating the substrates W or the components in the processing container 12.

The stay will be described with reference to FIG. 7. FIG. 7 schematically illustrates a state in which supercritical CO₂ ejected from the second fluid supplier 22 flows over a substrate W and is discharged from the fluid discharger 24 in a circulation process. After the supercritical CO₂ ejected from the second fluid supplier 22 collides with an end of the plate 18 of the tray 14, the supercritical CO₂ forms a vortex near the end, and this vortex stays at the same position. For example, when contaminants separated from the plate 18 are caught in the vortex, the contaminants may stay in the processing container 12 without being discharged from the processing container 12 and may re-adhere to the substrate W or the components in the processing container 12. By executing zig-zag control, the stay of contaminants can be prevented or greatly reduced.

In addition, according to the various embodiments described above, since the pressure in the processing container 12 is changed by changing the opening degree of the pressure control valve 40, abrupt changes in pressure in the processing container 12 and a piping system can be avoided. In contrast, if pressure-raising is performed by closing an opening/closing valve on the downstream side of the processing container 12 in the pressure-raising step of the circulation process, excessive pressure is temporarily generated in the processing container 12 and the piping system, which may cause damage to the components or may shorten the service life of the components.

In addition, according to the various embodiments described above, since the processing is always performed while the discharge line 38 is open, removal of contaminants in the processing container 12 and pipes and suppression of accumulation of contaminants can be expected. In addition, for example, when an opening/closing valve of the discharge line 38 is closed forcefully during the circulation process, the fluid containing contaminants may flow back into the processing container 12. However, by leaving the discharge line 38 open, no such problem arises.

Furthermore, according to the various embodiments described above, since the opening degree offset ΔX and the feedback gains are appropriately corrected, even if the pressure control valve 40 has changed over time, the pressure in the processing container 12 can be reliably maintained at a desired pressure.

### [Modification of Pressure-Raising Process]

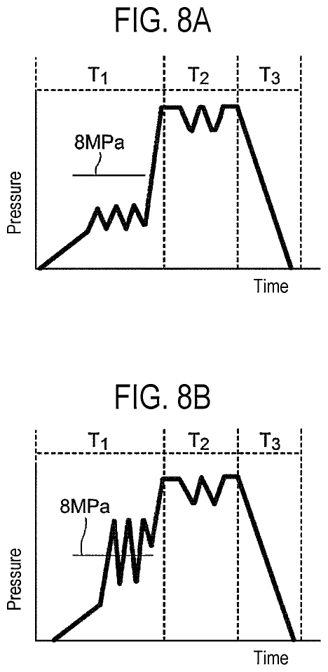

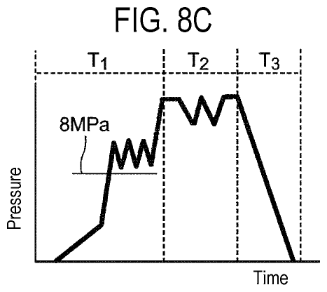

As illustrated in FIGS. 8A to 8C, the zigzag control may be performed not only during the circulation process but also during the pressure-raising process (normal pressure increase step). FIGS. 8A to 8C illustrate changes over time in pressure in the processing container 12, as in the upper portion of FIG. 4 described above. The zigzag control in the normal pressure-raising step may be performed in the same way as the zigzag control in the circulation process. That is, when the pressure sensor PS detects that the pressure in the processing container 12 has reached a predetermined pressure during the normal pressure-raising step, the pressure-lowering step and the pressure-raising step may be alternately repeated at least once in the same manner as the zigzag control in the circulation process (opening degree FP control).

This also changes the flow mode of CO₂ in the processing container 12, so that it is possible to prevent CO₂ from staying at a specific area in the processing container 12. The zig-zag control in the normal pressure-raising step may be performed while maintaining the pressure in the processing container 12 below about 8 MPa, the pressure at which the supercritical state of CO₂ (alone) is compensated for (FIG. 8A), or while maintaining the pressure in the processing container 12 above about 8 MPa (FIG. 8C). Alternatively, the zig-zag control in the normal pressure-raising step may be performed while varying the pressure in the processing container 12 between a pressure higher than about 8 MPa and a pressure lower than about 8 MPa (FIG. 8B). In this case, it can be expected that the phase change between the gas phase and the supercritical phase promotes the stay prevention effect.

The operation of FIG. 8B may increase the efficiency of removing contaminants in the processing container 12 and the pipes, but process performance may be degraded since the IPA puddles on the substrate W may evaporate in the gas phase. Therefore, it is assumed that the operation of FIG. 8B is basically performed in a state in which no substrate W is present in the processing container 12. However, the operation of FIG. 8B may be performed in the state in which a substrate W is present in the processing container 12 if the IPA puddles on the substrate W can be maintained.

It is to be considered that the embodiments disclosed herein are exemplary in all respects and not restrictive. The embodiments described above may be omitted, replaced, or modified in various forms without departing from the scope and spirit of the appended claims.

The substrate is not limited to a semiconductor wafer, and may be other types of substrates used in manufacturing semiconductor devices, such as glass substrates or ceramic substrates.

According to the above-described embodiments of the present disclosure, it is possible to suppress particles from staying in a processing container.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus to process a substrate by using a processing fluid in a supercritical state, the substrate processing apparatus comprising:
a processing container in which the substrate is accommodated;
a supply line connecting the processing container to a fluid source configured to send out the processing fluid in the supercritical state;
a discharge line configured to discharge the processing fluid from the processing container;
a control valve interposed in the discharge line; and
a controller configured to control a pressure in the processing container by adjusting an opening degree of the control valve,
wherein, the controller is configured to perform a circulation process in which the processing fluid is supplied to the processing container from the supply line while the pressure in the processing container is maintained within a pressure range in which the supercritical state of the processing liquid is maintained, and the processing fluid is discharged from the processing container,
wherein, in the circulation process, the controller is configured to adjust the opening degree of the control valve such that each of a pressure-lowering step of lowering the pressure in the processing container and a pressure-raising step of raising the pressure in the processing container is executed at least once within the pressure range.

2. The substrate processing apparatus of claim 1, wherein the controller executes the pressure-lowering step and the pressure-raising step alternately a plurality of times.

3. The substrate processing apparatus of claim 1, wherein the controller performs control of increase and decrease of the pressure in the processing container in the pressure-lowering step and the pressure-raising step only by adjusting the opening degree of the control valve.

4. The substrate processing apparatus of claim 1, wherein the control valve includes a valve body, a valve actuator configured to move the valve body, and a valve position sensor configured to detect a position of the valve body corresponding to the opening degree of the control valve or a valve opening degree corresponding to the position of the valve body,
wherein the controller is configured to perform a feedback control of the opening degree of the control valve in the pressure-lowering step and the pressure-raising step,
wherein one of a predetermined first position of the valve body at which a minimum pressure in the processing container to be finally achieved in the pressure-lowering step is capable of being achieved and a valve opening degree corresponding to the first position, and one of a predetermined second position of the valve body at which a maximum pressure in the processing container to be finally achieved in the pressure-raising step is capable of being achieved and a valve opening degree corresponding to the second position are used as target values in the feedback control,
wherein an actual position of the valve body detected by the valve position sensor or a valve opening degree corresponding to the actual position is used as an output value in the feedback control,
wherein the position of the valve body moved by the valve actuator or a change in the valve opening degree corresponding to the position of the valve body moved by the valve actuator is used as a manipulated amount in the feedback control, and
wherein the feedback control is performed by using a predetermined feedback gain depending on a deviation of the output value from the target value.

5. The substrate processing apparatus of claim 4, wherein, in a case where the pressure-lowering step and the pressure-raising step are alternately executed a plurality of times, the minimum pressures in respective pressure-lowering steps are equal to each other, and the maximum pressures in respective pressure-raising steps are equal to each other.

6. The substrate processing apparatus of claim 4, further comprising: a pressure sensor configured to detect the pressure itself in the processing container or a pressure in the discharge line in a vicinity of the processing container, wherein the pressure in the discharge line changes depending on a change in the pressure in the processing container,
wherein, when the pressure sensor detects that the pressure in the processing container has reached the minimum pressure in the pressure-lowering step during the execution of the pressure-lowering step, the controller switches the target value in the feedback control into the maximum value in the pressure-raising step to perform transition to the pressure-raising step.

7. The substrate processing apparatus of claim 6, wherein, when the pressure sensor detects that the pressure in the processing container has reached the maximum pressure in the pressure-raising step during the execution of the pressure-raising step, the controller switches the target value in the feedback control into the minimum value in the next pressure-lowering step to perform transition to the pressure-lowering step.

8. The substrate processing apparatus of claim 4, further comprising: a pressure sensor configured to detect the pressure itself in the processing container or a pressure in the discharge line in a vicinity of the processing container, wherein the pressure in the discharge line changes depending on a change in the pressure in the processing container,
wherein the controller includes:
a storage configured to store a change over time in the pressure detected by the pressure sensor and a target form of the change over time in the pressure; and
a calculator configured to correct, based on a result of comparison between the change over time in the pressure detected during the execution of the pressure-lowering step or the pressure-raising step and the target form of the change over time in the pressure, at least one of:
the target value in the feedback control selected from the group of the first position of the valve body, the valve opening degree corresponding to the first position, the second position of the valve body and the valve opening degree corresponding to the second position; and
at least one feedback gain of the feedback control.

9. The substrate processing apparatus of claim 1, wherein, in addition to the pressure-lowering step and the pressure-raising step, in the circulation process, the controller executes a constant-pressure step of keeping the pressure in the processing container constant within the pressure range at least once.

10. The substrate processing apparatus of claim 1, wherein, in the pressure-raising step of raising the pressure in the processing container from normal pressure to a pressure at which the supercritical state of the processing fluid is maintained, the controller adjusts the opening degree of the control valve to execute each of the pressure-lowering step of lowering the pressure in the processing container and the pressure-raising step of raising the pressure in the processing container at least once.

11. A substrate processing method of processing a substrate with a processing fluid in a supercritical state, the substrate processing method comprises:
a pressure-raising process of raising a pressure in a processing container from normal pressure to a pressure range in which the supercritical state of the processing fluid is maintained;
a circulation process performed after the pressure-raising process; and
an exhaust process performed after the circulation process,
wherein, in the circulation process, by adjusting an opening degree of a control valve interposed in a discharge line while maintaining the pressure in the processing container within the pressure range, each of a pressure-lowering step of lowering the pressure in the processing container within the pressure range and a pressure-raising step of raising the pressure in the processing container within the pressure range is executed at least once.

12. The substrate processing method of claim 11, wherein the pressure-lowering step and the pressure-raising step are alternately executed a plurality of times.

13. The substrate processing method of claim 11, wherein a control of lowering and raising of the pressure in the processing container in the pressure-lowering step and the pressure-raising step are performed by adjusting only the opening degree of the control valve.
